(19) United States
(12) Patent Application Publication
(10) Pub. No.: US 2026/0231507 A1
(43) Pub. Date: Aug. 6, 2026

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Kohei ADACHI, Tokyo (JP); Yutaka FUKUI, Tokyo (JP); Takaaki TOMINAGA, Tokyo (JP); Akifumi IIJIMA, Tokyo (JP)

(73) Assignee: Mitsubishi Electric Corporation, Tokyo (JP)

(21) Appl. No.: 19/351,182

(22) Filed: Oct. 6, 2025

(30) Foreign Application Priority Data
Feb. 3, 2025 (JP) 2025-016248

(51) Int. Cl. H10D 64/27; H10D 30/01; H10D 30/60; H10D 62/83; H10D 62/832; H10D 62/85

(52) U.S. Cl. CPC H10D 64/513; H10D 30/023; H10D 62/8303; H10D 62/8325; H10D 62/8503; H10D 64/518; H10D 30/611

(57) ABSTRACT

A semiconductor device according to the present disclosure includes a semiconductor substrate including a cell portion and an outer peripheral portion, a gate electrode provided inside a trench formed on an upper surface of the cell portion, a cell portion interlayer film inside the trench provided on the gate electrode, an outer peripheral portion interlayer film provided on an upper surface of a mesa portion adjacent to the trench in the outer peripheral portion, and a main electrode provided on the cell portion interlayer film and the outer peripheral portion interlayer film wherein the cell portion interlayer film includes a first cell portion interlayer film and a second cell portion interlayer film provided on the first cell portion interlayer film, and one of the first cell portion interlayer film and the second cell portion interlayer film includes impurities.

### BACKGROUND

### Field

The present disclosure relates to a semiconductor device and a method for manufacturing the semiconductor device.

### Background

JP 2022-170768 A discloses a semiconductor device having a trench gate structure. In the trench gate structure, a gate electrode is arranged in a trench with a gate insulating film interposed therebetween. Also, the inside of the trench is filled with an interlayer insulating film.

In order to reduce on-resistance of a MOSFET (Metal-Oxide-Semiconductor Field-Effect Transistor) or the like, it is desirable to reduce a cell pitch. However, in a semiconductor device with a narrow cell pitch, it may be difficult to fill the inside of the trench with an interlayer insulating film as in JP 2022-170768 A.

### SUMMARY

The present disclosure has been made to solve the above-described problem, and an object thereof is to provide a semiconductor device capable of filling an inside of a trench with an interlayer insulating film.

The features and advantages of the present disclosure may be summarized as follows.

According to an aspect of the present disclosure, a semiconductor device includes a semiconductor substrate including a cell portion and an outer peripheral portion outside the cell portion; a gate electrode provided inside a trench formed on an upper surface of the cell portion; a cell portion interlayer film inside the trench provided on the gate electrode; an outer peripheral portion interlayer film provided on an upper surface of a mesa portion adjacent to the trench in the outer peripheral portion; and a main electrode provided on the cell portion interlayer film and the outer peripheral portion interlayer film, and in contact with the cell portion interlayer film and the outer peripheral portion interlayer film, wherein the cell portion interlayer film includes a first cell portion interlayer film provided on the gate electrode, and a second cell portion interlayer film provided on the first cell portion interlayer film and in contact with the main electrode, and one of the first cell portion interlayer film and the second cell portion interlayer film includes impurities.

According to an aspect of the present disclosure, a semiconductor device includes a semiconductor substrate including a cell portion and an outer peripheral portion outside the cell portion; a gate electrode provided inside a trench formed on an upper surface of the cell portion; a cell portion interlayer film inside the trench provided on the gate electrode; an outer peripheral portion interlayer film provided on an upper surface of a mesa portion adjacent to the trench in the outer peripheral portion; and a main electrode provided on the cell portion interlayer film and the outer peripheral portion interlayer film and in contact with the cell portion interlayer film and the outer peripheral portion interlayer film, wherein the cell portion interlayer film includes impurities, the outer peripheral portion interlayer film includes a first outer peripheral portion interlayer film, and a second outer peripheral portion interlayer film provided on the first outer peripheral portion interlayer film and in contact with the main electrode, and a portion of an upper surface of the outer peripheral portion interlayer film directly above the mesa portion and an end face of the outer peripheral portion interlayer film above the mesa portion are formed of a same type of interlayer film.

According to an aspect of the present disclosure, a method for manufacturing a semiconductor device includes, in a semiconductor substrate including a cell portion and an outer peripheral portion outside the cell portion, forming a trench on an upper surface of the cell portion, forming a gate electrode inside the trench, forming a first interlayer film on an upper surface of the semiconductor substrate from the cell portion to the outer peripheral portion, etching the first interlayer film so that the first interlayer film remains inside the trench, after the etching of the first interlayer film, forming a second interlayer film on the upper surface of the semiconductor substrate from the cell portion to the outer peripheral portion such that the second interlayer film is formed on the first interlayer film inside the trench, etching the second interlayer film so that the second interlayer film remains inside the trench and in the outer peripheral portion, and after the etching of the second interlayer film, forming a main electrode on the second interlayer film so as to be in contact with the second interlayer film, wherein one of the first interlayer film and the second interlayer film includes impurities.

Other and further objects, features and advantages of the disclosure will appear more fully from the following description.

### BRIEF DESCRIPTION OF DRAWINGS

FIG. 1 is a cross-sectional view of the semiconductor device according to Embodiment 1.

FIG. 2 is a cross-sectional view showing a state in which a main electrode is provided in the semiconductor device according to Embodiment 1.

FIGS. 3A to 3D are diagrams explaining the method for manufacturing the semiconductor device according to Embodiment 1.

FIG. 4 is a flowchart showing the method for manufacturing the semiconductor device according to Embodiment 1.

FIG. 5 is a cross-sectional view of the semiconductor device according to a modification of Embodiment 1.

FIG. 6 is a cross-sectional view of a semiconductor device according to Embodiment 2.

FIG. 7 is a cross-sectional view showing a state in which the main electrode is provided in the semiconductor device according to Embodiment 2.

FIGS. 8A to 8D are diagrams illustrating the method for manufacturing the semiconductor device according to Embodiment 2.

FIG. 9 is a diagram illustrating the method for manufacturing the semiconductor device according to the first modification of Embodiment 2.

FIG. 10 is a cross-sectional view of the semiconductor device according to the second modification of Embodiment 2.

FIG. 11 is a cross-sectional view of the semiconductor device according to Embodiment 3.

FIG. 12 is a plan view of the semiconductor device according to Embodiment 3.

FIG. 13 is a cross-sectional view of the semiconductor substrate according to Embodiment 4.

### DESCRIPTION OF EMBODIMENTS

A semiconductor device and a method for manufacturing the semiconductor device according to each embodiment will be described with reference to the drawings. The same reference numerals are assigned to the same or corresponding components, and the repetition of the description may be omitted.

### Embodiment 1

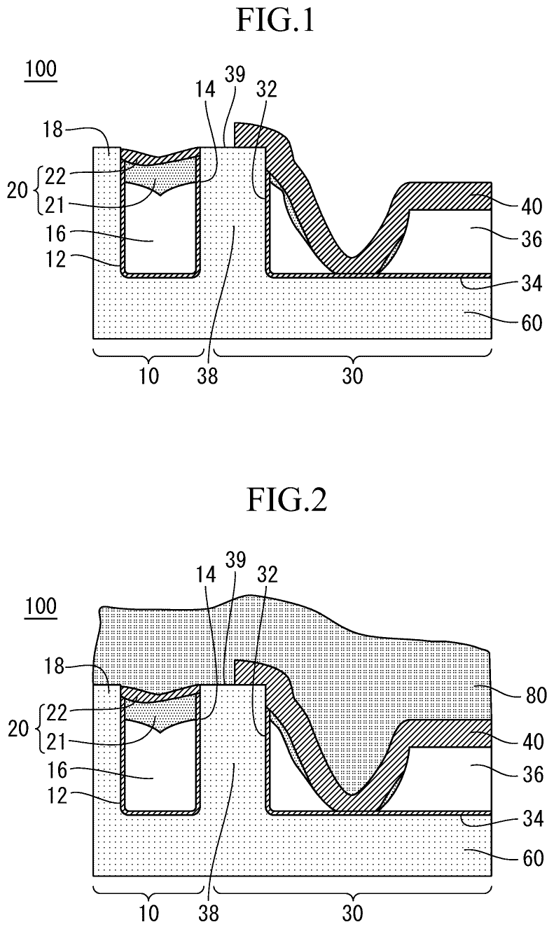

FIG. 1 is a cross-sectional view of the semiconductor device 100 according to Embodiment 1. FIG. 2 is a cross-sectional view showing a state in which a main electrode 80 is provided in the semiconductor device 100 according to Embodiment 1. The semiconductor device 100 includes a semiconductor substrate 60 having a cell portion 10 that is an active area through which a main current flows, and an outer peripheral portion 30 outside the cell portion 10. The outer peripheral portion 30 is also called a termination region. In FIG. 1, various semiconductor layers and a back electrode provided on the semiconductor substrate 60 are omitted. FIGS. 1 and 2 show a boundary portion between the cell portion 10 and the outer peripheral portion 30.

A trench 12 is formed on the upper surface of the cell portion 10. That is, the trench 12 shown in FIGS. 1 and 2 is the trench 12 closest to the outer periphery portion 30 among the plurality of trenches 12 formed in the cell portion 10. A portion between adjacent trenches 12 in the cell portion 10 is a mesa portion 18. A gate electrode 16 is provided inside the trench 12. The gate electrode 16 is formed of, for example, polysilicon. A cell portion interlayer film 20 is provided on the gate electrode 16 inside the trench 12. An inner wall of the trench 12 is covered with a gate oxide film 14. The gate electrode 16 and the cell portion interlayer film 20 are in contact with the semiconductor substrate 60 via the gate oxide film 14.

A mesa portion 38 adjacent to the trench 12 of the cell portion 10 is provided in the outer peripheral portion 30. An outer peripheral portion interlayer film 40 is provided on the upper surface of the mesa portion 38. The outer peripheral portion interlayer film 40 is, for example, a single layer.

An outer peripheral portion trench 32 is formed on the upper surface of the outer peripheral portion 30 of the semiconductor substrate 60. A gate oxide film 34 is provided inside the outer peripheral portion trench 32. The inner wall of the outer peripheral portion trench 32 is covered with the gate oxide film 34. An outer peripheral portion gate electrode 36 is provided on the gate oxide film 34 inside the outer peripheral portion trench 32. The outer peripheral portion gate electrode 36 is formed of, for example, polysilicon. The outer peripheral portion interlayer film 40 is provided on the peripheral portion gate electrode 36. That is, the peripheral portion gate electrode 36 and the outer peripheral portion interlayer film 40 are in contact with the semiconductor substrate 60 via the gate oxide film 34. The outer peripheral portion interlayer film 40 is formed so as to extend from the inside of the outer peripheral portion trench 32 onto the mesa portion 38. By forming a trench in the outer peripheral portion 30, irregularities in the wafer surface can be reduced. Therefore, stress due to steps or the like can be reduced, and reliability can be improved.

A main electrode 80 is provided on the cell portion interlayer film 20 and the outer peripheral portion interlayer film 40, and is in contact with the cell portion interlayer film 20 and the outer peripheral portion interlayer film 40. The main electrode 80 is, for example, a source electrode or an emitter electrode. The outer peripheral portion interlayer film 40 is provided so as to expose a part of the mesa portion 38. The main electrode 80 is in contact with the semiconductor substrate 60 at an exposed portion 39, which is the part of the mesa portion 38 exposed from the outer peripheral portion interlayer film 40. This ensures contact between the mesa portion 38 and the main electrode 80, which is required at the boundary between the cell portion 10 and the outer peripheral portion 30.

The cell portion interlayer film 20 includes a first cell portion interlayer film 21 provided on the gate electrode 16, and a second cell portion interlayer film 22 provided on the first cell portion interlayer film 21 and in contact with the main electrode 80. One of the first cell portion interlayer film 21 and the second cell portion interlayer film 22 contains impurities. In the present embodiment, as an example, the first cell portion interlayer film 21 contains impurities, and the second cell portion interlayer film 22 has an impurity concentration lower than that of the first cell portion interlayer film 21. The second cell portion interlayer film 22 may not contain impurities.

The outer peripheral portion interlayer film 40 is formed of an interlayer film with a lower impurity concentration than the first cell portion interlayer film 21. The outer peripheral portion interlayer film 40 may not contain impurities. When the outer peripheral portion interlayer film 40 is formed of a plurality of layers, it is sufficient that the uppermost surface of the outer peripheral portion interlayer film 40 that contacts the main electrode 80 is formed of an interlayer film with a lower impurity concentration than the first cell portion interlayer film 21. Further, the interlayer film forming the uppermost surface of the outer peripheral portion interlayer film 40 may not contain impurities.

In the present embodiment, two layers of interlayer films are buried in a trench 12 in a cell portion 10. On the other hand, the outer peripheral portion interlayer film 40 riding on the mesa portion 38 is a single layer. The first cell portion interlayer film 21, the second cell portion interlayer film 22, and the outer peripheral portion interlayer film 40 are, for example, oxide films. Specifically, the first cell portion interlayer film 21 is, for example, a BPSG (Boron Phosphorus Silicon Glass) film. The second cell portion interlayer film 22 and the outer peripheral portion interlayer film 40 are, for example, TEOS (Tetra Ethoxy Silane) films.

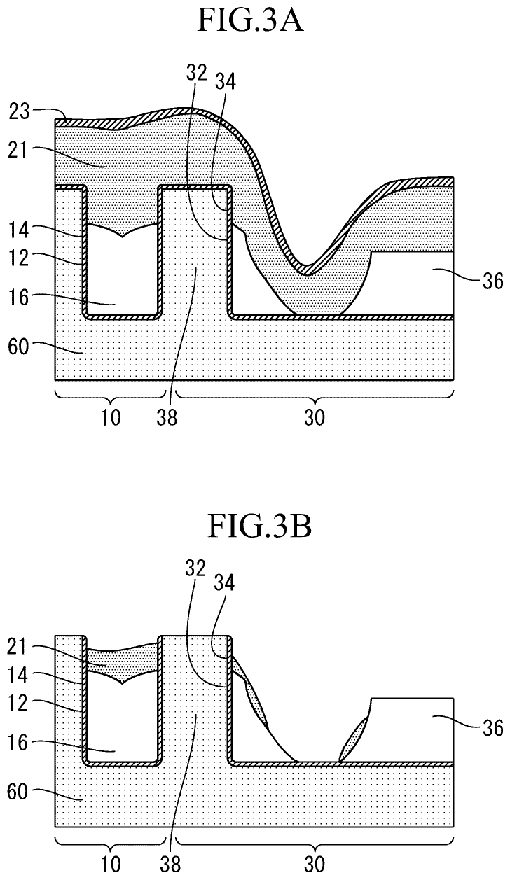

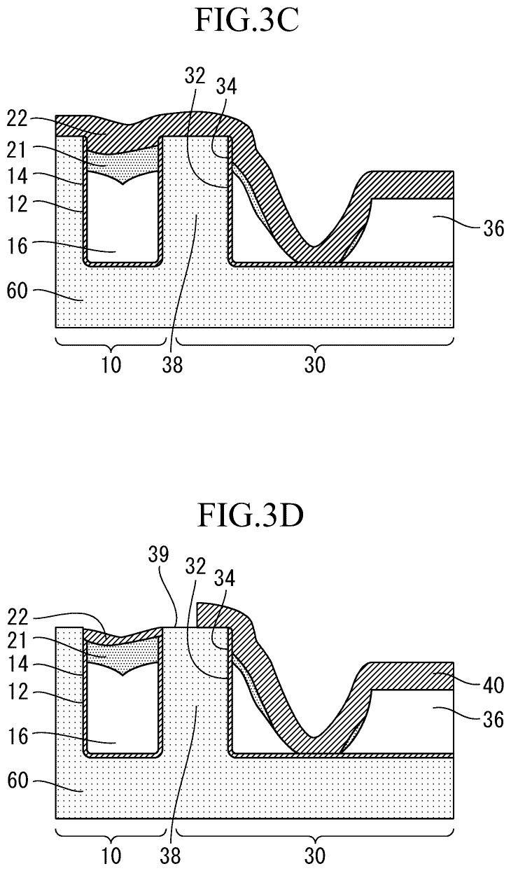

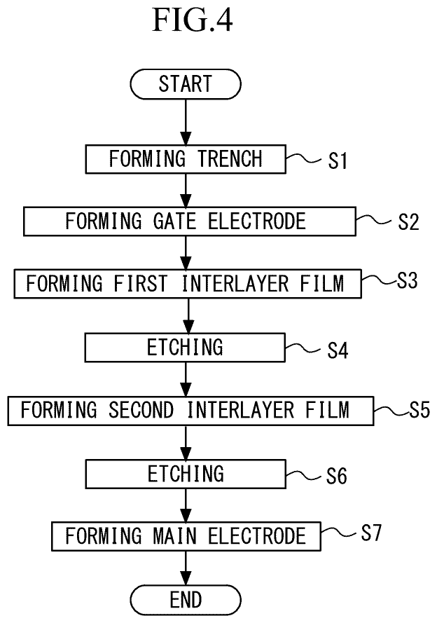

Next, a method for manufacturing the semiconductor device 100 will be described. FIGS. 3A to 3D are diagrams illustrating the method for manufacturing the semiconductor device 100 according to Embodiment 1. FIG. 4 is a flowchart showing the method for manufacturing the semiconductor device 100 according to Embodiment 1. For example, an N-type silicon carbide substrate is used as the semiconductor substrate 60. The semiconductor device 100 is formed on a base material in which a silicon carbide epitaxial layer is formed on a silicon carbide substrate. First, impurities are implanted into the epitaxial layer to form a semiconductor layer of an arbitrary conductivity type. For example, Al can be implanted to form a P-type semiconductor layer, and N can be implanted to form an N-type semiconductor layer.

After implanting the impurities, a trench step for forming the trench 12 is performed (step 1). In the trench step, first, an oxide film is deposited on the semiconductor substrate 60, and then a resist is deposited. Next, the resist is patterned along the shape of the trench 12. Next, the oxide film is etched using the resist pattern. Thereby, a hard mask for forming trenches in the epitaxial layer can be formed of the oxide film. Next, the silicon carbide is etched through the hard mask. Thereby, the trench 12 can be formed on the upper surface of the cell portion 10. The trench 12 extends vertically to the semiconductor substrate 60. The outer peripheral portion trench 32 can be formed in the same manner as the trench 12, or simultaneously with the trench 12.

After the trench step, impurities may be implanted into the bottom of the trench 12 to form a P-type field relaxation layer. By using the hard mask in the trench step, the P-type field relaxation layer can be selectively formed at the bottom of the trench 12. Providing the field relaxation layer can improve gate reliability. According to the trench 12 substantially perpendicular to the semiconductor substrate 60, the field relaxation layer can be formed more stably.

Next, the hard mask is removed. Next, an impurity implantation step may be performed to form an additional N-type or P-type impurity layer on a portion of the sidewall of the trench 12 that is perpendicular to the semiconductor substrate 60. Particularly, in the semiconductor device in which the field relaxation layer is provided at the bottom of the trench, it is desirable to form a P-layer on the sidewall of the trench 12 in order to make the potential of the field relaxation layer common to the P-layer in the middle of the trench 12.

In addition, in the cell portion 10, an implantation step of changing a part of the portion where the semiconductor layer is in contact with the metal electrode from N-type to P-type is performed. At this time, in particular, a gate pull-up portion surrounded by gate wiring may cause an increase in leakage current. Therefore, it is desirable that the gate pull-up portion be subjected to impurity implantation so as to be P-type, including portions not in contact with the gate wiring. It is presumed that the reason for the large leakage current in the N-type semiconductor is that the excessive amount of electrons with high mobility tends to increase the leakage current.

After performing all the impurity implantation steps, heat treatment is performed to activate the implanted impurity layers. After the heat treatment, a desired insulating film forming step and a gate oxide film forming step are performed respectively. In the gate oxide film forming step, the gate oxide films 14 and 34 are formed.

Next, a gate wiring step is performed. In the gate wiring step, a gate wiring is obtained by depositing polysilicon and then patterning it into an arbitrary shape. This gate wiring includes the gate electrode 16 inside the trench 12 and the outer peripheral portion gate electrode 36 inside the outer peripheral portion trench 32 (step 2). In the step of patterning the gate wiring, the gate wiring in the portion embedded in the trench 12 of the cell portion 10 is etched. That is, the gate wiring that covers the top of the trench 12 in the cell portion 10 is etched back. Subsequently, an oxide film may be formed on the gate wiring by thermal oxidation or the like, if necessary.

Next, a first interlayer film is formed on the upper surface of the semiconductor substrate 60 from the cell portion 10 to the outer peripheral portion 30 (step 3). The first interlayer film corresponds to the first cell portion interlayer film 21. In this step, as shown in FIG. 3A, two or more interlayer films may be formed as the interlayer film. Also, only one interlayer film may be formed.

As the two-layer interlayer film, for example, the first cell portion interlayer film 21 containing impurity elements, having high fluidity, and having high trench 12 embedding properties, and an interlayer film 23 containing no impurity elements and having high reliability are used. The impurity elements are, for example, boron (B) or phosphorus (P). The first cell portion interlayer film 21 is, for example, a BPSG film, and the interlayer film 23 is, for example, a TEOS film. In the case of using two layers of interlayer films, it is desirable that after embedding the trench 12 and the outer peripheral portion trench 32 with the first cell portion interlayer film 21 containing impurity elements, the entire surface is covered with the interlayer film 23 containing no impurity element.

When forming a single layer of interlayer film, the first cell portion interlayer film 21 containing impurity elements is used in order to improve the embedding property into the trench 12. Also, before forming the first cell portion interlayer film 21, an interlayer film containing no impurity element may be formed as a base.

Next, as shown in FIG. 3B, the first cell portion interlayer film 21 and the interlayer film 23 are etched such that the first cell portion interlayer film 21 remains inside the trench 12 (step 4). That is, by etching back the entire surface of the wafer, the first cell portion interlayer film 21 remains only in the trench 12. The interlayer films of the cell portion 10 excluding the inside of the trench 12 and the mesa portion 38 of the outer peripheral portion 30 are all etched.

Next, as shown in FIG. 3C, after etching the first cell portion interlayer film 21, a second interlayer film is formed on the upper surface of the semiconductor substrate 60 from the cell portion 10 to the outer peripheral portion 30 (step 5). The second interlayer film corresponds to the second cell portion interlayer film 22 that does not contain impurity elements. At this time, the second cell portion interlayer film 22 is formed on the first cell portion interlayer film 21 inside the trench 12.

Next, as shown in FIG. 3D, the second cell portion interlayer film 22 is etched so that the second cell portion interlayer film 22 remains inside the trench 12 and on the outer peripheral portion 30 (step 6). Specifically, with the portion of the mask covering the cell portion 10 patterned by photolithography to form an opening in the mask, etch back is performed. Thereby, the second cell portion interlayer film 22 within the trench 12 is thinned, and the upper surface of the semiconductor substrate 60 is exposed from the second cell portion interlayer film 22 in the cell portion 10. That is, only the inside of the trench 12 in the cell portion 10 can be filled with the interlayer film. By this step, the second cell portion interlayer film 22 becomes thinner than the outer peripheral portion interlayer film 40. The etch-back amount in step 6 is adjusted to the amount that the second cell portion interlayer film 22 remains in the trench 12. Note that the portion remaining in the outer peripheral portion 30 of the second cell portion interlayer film 22 becomes the outer peripheral portion interlayer film 40.

Thereafter, the main electrode 80 is formed in a surface metallization step (step 7). The main electrode 80 is formed on the second cell portion interlayer film 22 and the outer peripheral portion interlayer film 40 so as to be in contact with the second cell portion interlayer film 22 and the outer peripheral portion interlayer film 40.

Next, the semiconductor device 100 is manufactured through a passivation film forming step, a protective film forming step, a grinding step, a back surface metallization step, a dicing step, a test step, and the like. The semiconductor device 100 is modularized or the like, and finally constitutes an inverter circuit or the like.

In the present embodiment, the trench 12 is filled with the first cell portion interlayer film 21 containing impurities and having high gap-filling properties. Therefore, even when a cell pitch is narrow, the inside of the trench 12 can be filled with an interlayer insulating film. Thereby, reduction of on-resistance and thus energy loss due to the reduction of the cell pitch can be realized.

In addition, if the main electrode 80 is in contact with the interlayer film containing impurity elements, the insulation properties when a high voltage is applied may be degraded, and the reliability may be reduced due to leakage current. In contrast, in the present embodiment, the second cell portion interlayer film 22 and the outer peripheral portion interlayer film 40 that contact the main electrode 80 are formed of an interlayer film that does not contain impurity elements. Therefore, the reliability of the device can be improved.

Note that the second cell portion interlayer film 22 and the outer peripheral portion interlayer film 40 may contain some impurities. For example, the impurity concentration of the second cell portion interlayer film 22 and the outer peripheral portion interlayer film 40 may be lower than that of the first cell portion interlayer film 21.

Also, the stacking order of the first cell portion interlayer film 21 and the second cell portion interlayer film 22 is not limited. That is, the interlayer film containing impurities may be provided on the interlayer film not containing impurities. Also, the interlayer film containing impurities may be applied to the outer peripheral portion interlayer film 40.

In the present embodiment, an example in which the semiconductor substrate 60 is formed of a wide band gap semiconductor has been described. The wide band gap semiconductor may be a gallium nitride-based material or diamond, in addition to the silicon carbide described above. Also, the semiconductor substrate 60 may be a silicon substrate. In any case, it is possible to stably form an interlayer film and improve reliability.

The semiconductor device 100 of the present embodiment can be applied to any semiconductor device such as a MOSFET, an IGBT (Insulated Gate Bipolar Transistor).

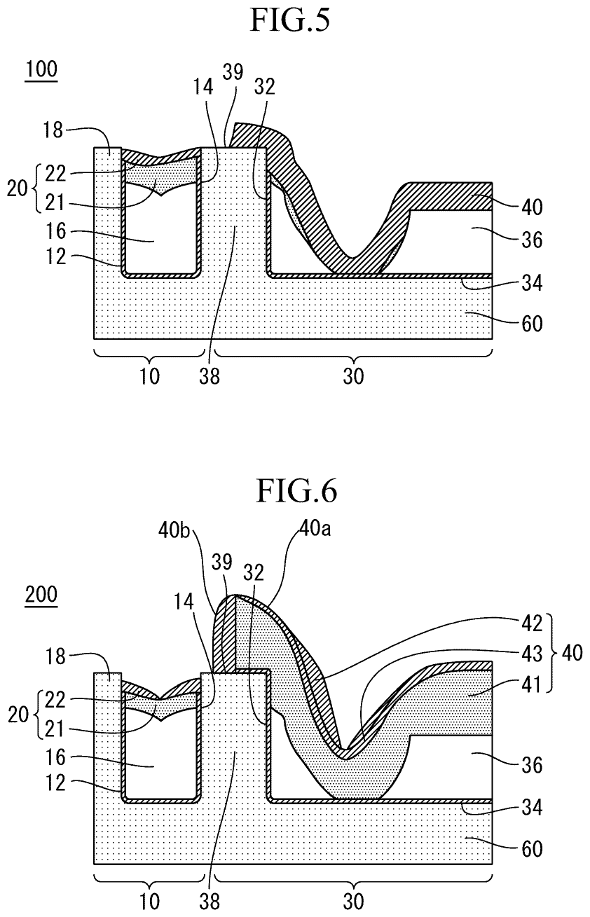

FIG. 5 is a cross-sectional view of the semiconductor device 100 according to a modification of Embodiment 1. In step 6 of the etch-back, the end portion of the outer peripheral portion interlayer film 40 adjacent to the trench 12 may be etched into a tapered shape. This can improve the filling performance in the metallization step.

The above-described modifications can be applied as appropriate to the semiconductor device and the method for manufacturing a semiconductor device according to the following embodiments. Since the semiconductor device and the method for manufacturing a semiconductor device according to the following embodiments have many points in common with Embodiment 1, the description will focus on the differences from Embodiment 1.

### Embodiment 2

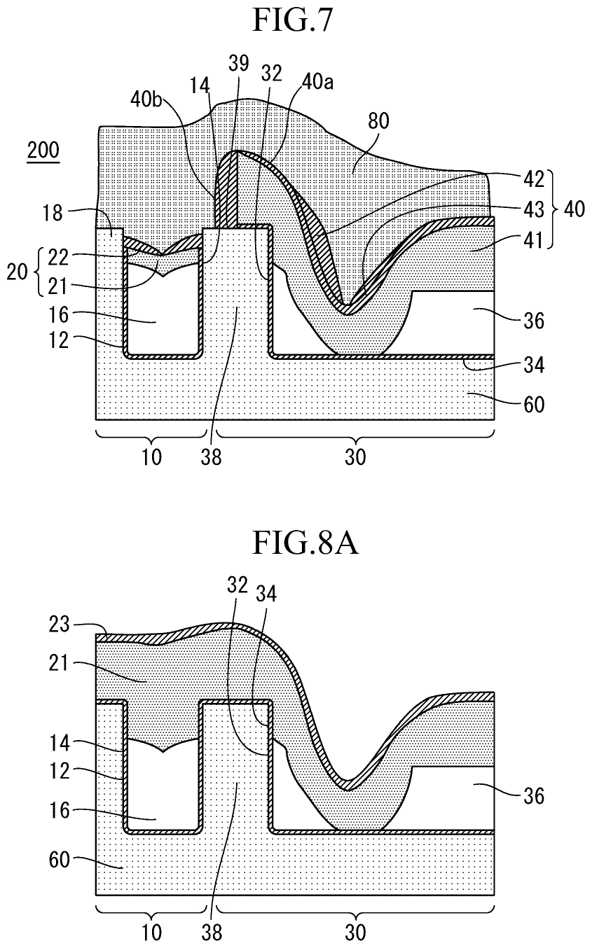

FIG. 6 is a cross-sectional view of the semiconductor device 200 according to Embodiment 2. FIG. 7 is a cross-sectional view illustrating a state in which the main electrode 80 is provided in the semiconductor device 200 according to Embodiment 2. In the present embodiment, the outer peripheral portion interlayer film 40 provided on the upper surface of the mesa portion 38 includes the first outer peripheral portion interlayer film 41, the second outer peripheral portion interlayer film 42, and the interlayer film 43 provided between the first outer peripheral portion interlayer film 41 and the second outer peripheral portion interlayer film 42. The second outer peripheral portion interlayer film 42 is provided on the first outer peripheral portion interlayer film 41 and is in contact with the main electrode 80.

Note that the interlayer film 43 may be the same type of film as the second outer peripheral portion interlayer film 42, or may be a different type of film. The interlayer film 43 may be omitted. That is, the outer peripheral portion interlayer film 40 riding on the mesa portion 38 only needs to be formed of two or more interlayer films. The first outer peripheral portion interlayer film 41 contains impurities. The second outer peripheral portion interlayer film 42 and the interlayer film 43 have a lower impurity concentration than the first outer peripheral portion interlayer film 41. The second outer peripheral portion interlayer film 42 and the interlayer film 43 may not contain impurities. The first outer peripheral portion interlayer film 41, the second outer peripheral portion interlayer film 42, and the interlayer film 43 are, for example, oxide films. Specifically, the first outer peripheral portion interlayer film 41 is, for example, a BPSG film. The second cell portion interlayer film 22 and the interlayer film 43 are, for example, TEOS films.

In the present embodiment, of the upper surface of the outer peripheral portion interlayer film 40, a portion 40a directly above the mesa portion 38 and an end face 40b on the mesa portion 38 are formed of the same type of interlayer film. This same type of interlayer film is the second outer peripheral portion interlayer film 42 or the interlayer film 43. The portion of the outer peripheral portion interlayer film 40 directly above the mesa portion 38 may be entirely covered with the second outer peripheral portion interlayer film 42 or the interlayer film 43.

The configuration of the cell portion interlayer film 20 is the same as the configuration of Embodiment 1. Of the cell portion interlayer film 20, the uppermost surface in contact with the main electrode 80, that is, the second cell portion interlayer film 22, is formed of an interlayer film with a lower impurity concentration than the first outer peripheral portion interlayer film 41. The second cell portion interlayer film 22 forming the uppermost surface of the cell portion interlayer film 20 may not include impurities. In this embodiment, the cell portion interlayer film 20 may be formed of one or more interlayer films. The cell portion interlayer film 20 contains impurities. Thereby, the filling property into the trench 12 can be improved.

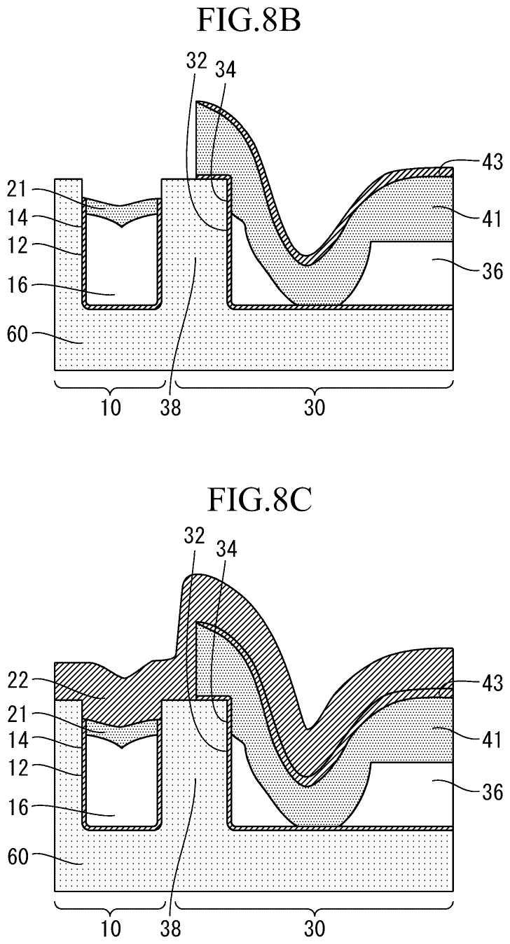

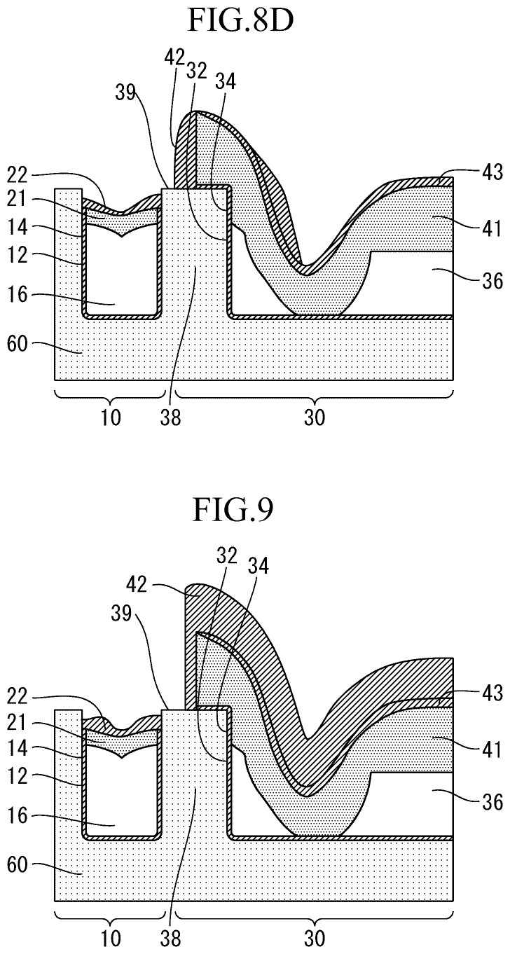

FIGS. 8A to 8D are diagrams illustrating a method for manufacturing the semiconductor device 200 according to Embodiment 2. The process up to the step 3 of forming the first cell portion interlayer film 21 and the interlayer film 23 is the same as the manufacturing method for Embodiment 1

In step 4, a portion of the mask covering the cell portion 10 is patterned by photolithography to form an opening. Etch-back is performed using this mask. Thereby, as shown in FIG. 8B, in the cell portion 10, the first cell portion interlayer film 21 can be left only in the trench 12. Also, in the outer peripheral portion 30, a part of the mesa portion 38 is exposed from the interlayer film. Of the first cell portion interlayer film 21 and the interlayer film 23, portions left in the outer peripheral portion 30 become the first outer peripheral portion interlayer film 41 and the interlayer film 43. By this process, the first cell portion interlayer film 21 is formed thinner than the first outer peripheral portion interlayer film 41.

Next, as shown in FIG. 8C, a second inter-cell-region interlayer film 22 is formed as a second interlayer film (step 5). Next, as shown in FIG. 8D, the entire surface of the wafer is etched back (step 6). As a result, in the cell portion 10, only the inside of the trench 12 is filled with the second inter-cell-region interlayer film 22. In addition, an exposed portion 39 is formed on the mesa portion 38. The portion of the second inter-cell-region interlayer film 22 remaining on the outer peripheral portion 30 becomes the second outer peripheral portion interlayer film 42. In step 6, the etch-back amount is adjusted such that the second interlayer film remains on the wafer surface in the cell portion 10 and the outer peripheral portion 30. The subsequent steps are similar to those of Embodiment 1.

FIG. 9 is a diagram illustrating a method for manufacturing the semiconductor device 200 according to the first modification of Embodiment 2. Instead of etching back the entire surface of the wafer in step 6, only the second cell portion interlayer film 22 of the cell portion 10 may be etched. At this time, the same mask as in step 4 may be used. As a result, the interlayer film of the outer peripheral portion 30 can be left thick, and reliability can be improved.

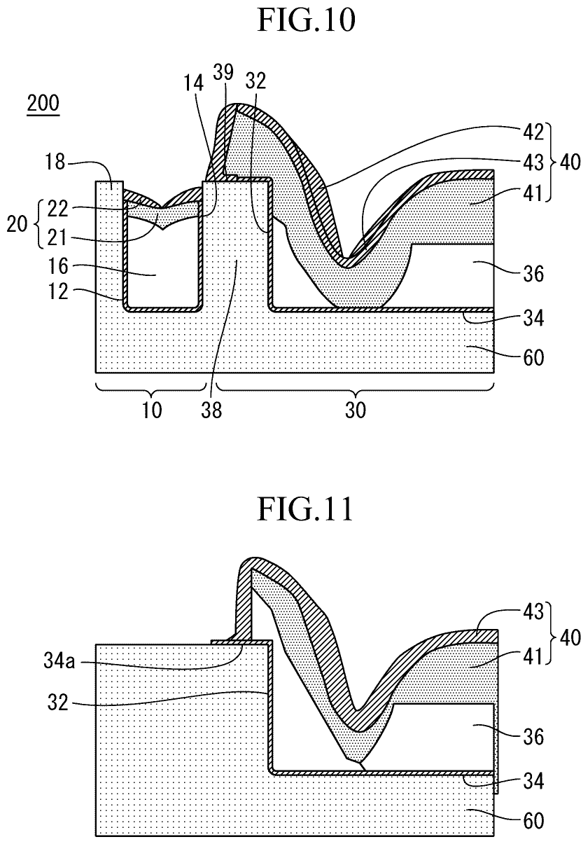

FIG. 10 is a cross-sectional view of the semiconductor device 200 according to the second modification of Embodiment 2. An end portion of the first outer peripheral portion interlayer film 41 adjacent to the trench 12 may be tapered. That is, the end portion of the first outer peripheral portion interlayer film 41 may be etched into a tapered shape during the etch-back in step 4. This facilitates the adhesion of the second outer peripheral portion interlayer film 42 to the end face of the first outer peripheral portion interlayer film 41 in step 5. Therefore, the first outer peripheral portion interlayer film 41 is less likely to be exposed, and reliability can be improved.

In the present embodiment, of the outer peripheral portion interlayer film 40, the portion that rides onto the mesa portion 38 is formed of two or more types of interlayer films. The interlayer film including impurity elements remains inside the portion that rides onto the mesa portion 38, and the surface is covered with an interlayer film not including an impurity element. According to such a structure, only the interlayer film not including the impurity element comes into contact with the main electrode 80. Therefore, the reliability of the device can be ensured. Also, similarly to Embodiment 1, since the trench 12 is filled with the first cell portion interlayer film 21 containing impurities and having high filling properties, the inside of the trench 12 can be filled with the interlayer insulating film even when the cell pitch is narrow.

Furthermore, in this embodiment, since the portion of the interlayer film 40 on the outer peripheral portion that rides onto the mesa portion 38 is thick, the leakage current can be made smaller than in Embodiment 1. On the other hand, in Embodiment 1, since the flatness of the electrodes can be improved more than in Embodiment 2, the resistance to stress and the like can be improved.

### Embodiment 3

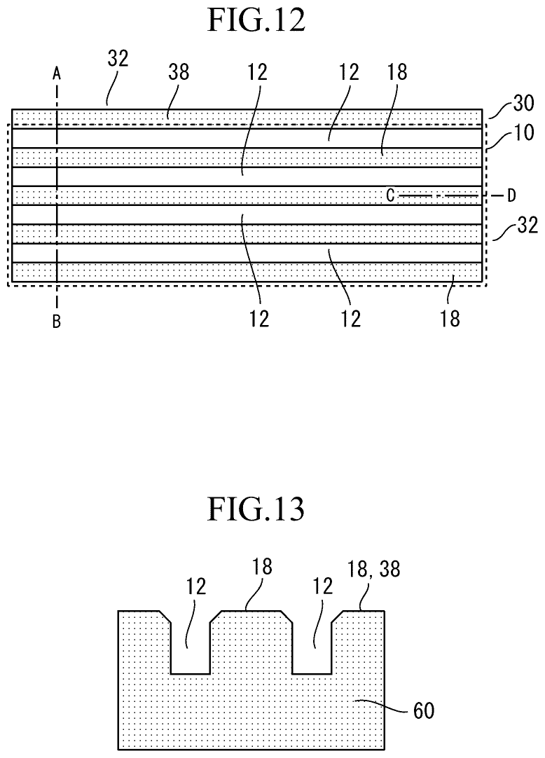

FIG. 11 is a cross-sectional view of the semiconductor device according to Embodiment 3. FIG. 12 is a plan view of the semiconductor device according to Embodiment 3. In the semiconductor device, a plurality of trenches 12 are formed in a stripe shape. Note that FIGS. 1 and 6 are cross-sectional views obtained by cutting FIG. 12 along the line A-B. FIG. 11 is a cross-sectional view obtained by cutting FIG. 12 along the line C-D. That is, FIG. 11 shows a gate lead-out portion at the longitudinal end of the trench 12.

The gate oxide film 34 and the outer peripheral portion gate electrode 36 are formed so as to extend from the inside of the outer peripheral portion trench 32 onto the upper surface of the semiconductor substrate 60 of the cell portion 10. At this time, a portion 34a of the gate oxide film 34, which is provided on the upper surface of the semiconductor substrate 60 of the cell portion 10, may be thicker than a portion of the gate oxide film 14 provided inside the trench 12. This can improve reliability in a portion where the gate wiring rides on a corner of the trench 12. It should be noted that, of the gate oxide film 34, a portion provided inside the outer peripheral portion trench 32 may have the same thickness as the portion 34a, or may have the same thickness as the gate oxide film 14. The features of this embodiment may be combined with any of Embodiments 1 and 2.

### Embodiment 4

FIG. 13 is a cross-sectional view of the semiconductor substrate 60 according to Embodiment 4. The corners of the semiconductor substrate 60 forming the opening of the trench 12 may be formed with an obtuse angle or a curved surface. This can improve the filling properties of the gate electrode 16 and t the cell portion interlayer film 20 into the trench 12.

The trench 12 shown in FIG. 13 can be formed by forming the vertical portion of the trench 12 and then adding a step of forming an inclined portion or curvature at the upper corners of the trench 12. Specifically, after forming the vertical portion of the trench 12, a mask reduction step is performed in which the hard mask forming the trench 12 is, for example, wet-etched to reduce the hard mask by an arbitrary dimension. As a result, a portion of the periphery of the trench 12 on the upper surface of the semiconductor substrate 60 is exposed from the hard mask. By performing dry etching such as reactive ion etching on this exposed portion, an inclined portion or a curved surface can be formed at the corner of the trench 12. After this, the hard mask is removed. The feature of this embodiment may be combined with either Embodiment 1 or 2.

The technical features described in each embodiment may be combined and used as appropriate.

Hereinafter, various aspects of the present disclosure will be collectively described as appendixes.

### Appendix 1

A semiconductor device comprising:

a semiconductor substrate including a cell portion and an outer peripheral portion outside the cell portion;

a gate electrode provided inside a trench formed on an upper surface of the cell portion;

a cell portion interlayer film inside the trench provided on the gate electrode;

an outer peripheral portion interlayer film provided on an upper surface of a mesa portion adjacent to the trench in the outer peripheral portion; and

a main electrode provided on the cell portion interlayer film and the outer peripheral portion interlayer film, and in contact with the cell portion interlayer film and the outer peripheral portion interlayer film, wherein

the cell portion interlayer film includes a first cell portion interlayer film provided on the gate electrode, and a second cell portion interlayer film provided on the first cell portion interlayer film and in contact with the main electrode, and

one of the first cell portion interlayer film and the second cell portion interlayer film includes impurities.

### Appendix 2

The semiconductor device according to appendix 1, wherein the first cell portion interlayer film includes impurities,

the second cell portion interlayer film has a lower impurity concentration than the first cell portion interlayer film, and

an uppermost surface of the outer peripheral portion interlayer film that is in contact with the main electrode is formed of an interlayer film having a lower impurity concentration than the first cell portion interlayer film.

### Appendix 3

The semiconductor device according to appendix 2, wherein the second cell portion interlayer film and the interlayer film forming the uppermost surface of the outer peripheral portion interlayer film do not include impurities.

### Appendix 4

The semiconductor device according to any one of appendixes 1 to 3, wherein the outer peripheral portion interlayer film is a single layer.

### Appendix 5

The semiconductor device according to any one of appendixes 1 to 4, wherein the second cell portion interlayer film is thinner than the outer peripheral portion interlayer film.

### Appendix 6

The semiconductor device according to any one of appendixes 1 to 5, wherein an end portion adjacent to the trench, of the outer peripheral portion interlayer film is tapered.

### Appendix 7

A semiconductor device comprising:

a semiconductor substrate including a cell portion and an outer peripheral portion outside the cell portion;

a gate electrode provided inside a trench formed on an upper surface of the cell portion;

a cell portion interlayer film inside the trench provided on the gate electrode;

an outer peripheral portion interlayer film provided on an upper surface of a mesa portion adjacent to the trench in the outer peripheral portion; and

a main electrode provided on the cell portion interlayer film and the outer peripheral portion interlayer film and in contact with the cell portion interlayer film and the outer peripheral portion interlayer film, wherein

the cell portion interlayer film includes impurities,

the outer peripheral portion interlayer film includes a first outer peripheral portion interlayer film, and a second outer peripheral portion interlayer film provided on the first outer peripheral portion interlayer film and in contact with the main electrode, and

a portion of an upper surface of the outer peripheral portion interlayer film directly above the mesa portion and an end face of the outer peripheral portion interlayer film above the mesa portion are formed of a same type of interlayer film.

### Appendix 8

The semiconductor device according to appendix 7, wherein the first outer peripheral portion interlayer film includes impurities,

the second outer peripheral portion interlayer film has a lower impurity concentration than the first outer peripheral portion interlayer film,

the interlayer film of the same type is the second outer peripheral portion interlayer film, and

an uppermost surface of the cell portion interlayer film that is in contact with the main electrode is formed of an interlayer film having a lower impurity concentration than the first outer peripheral portion interlayer film.

### Appendix 9

The semiconductor device according to appendix 8, wherein the second outer peripheral portion interlayer film and the interlayer film forming the uppermost surface of the cell portion interlayer film do not include impurities.

### Appendix 10

The semiconductor device according to any one of appendixes 7 to 9, wherein the cell portion interlayer film includes a first cell portion interlayer film provided on the gate electrode and a second cell portion interlayer film provided on the first cell portion interlayer film and in contact with the main electrode, and

the first cell portion interlayer film is thinner than the first outer peripheral portion interlayer film.

### Appendix 11

The semiconductor device according to any one of appendixes 7 to 10, wherein an end portion adjacent to the trench, of the first outer peripheral portion interlayer film is tapered.

### Appendix 12

The semiconductor device according to any one of appendixes 1 to 11, wherein the outer peripheral portion interlayer film is provided so as to expose a part of the mesa portion, and

the main electrode is in contact with the semiconductor substrate in the part of the mesa portion exposed from the outer peripheral portion interlayer film.

### Appendix 13

The semiconductor device according to any one of appendixes 1 to 12, wherein an outer peripheral portion trench is formed on an upper surface of the outer peripheral portion of the semiconductor substrate.

### Appendix 14

The semiconductor device according to appendix 13, wherein the outer peripheral portion interlayer film is formed so as to extend from an inside of the outer peripheral portion trench onto the mesa portion.

### Appendix 15

The semiconductor device according to appendix 13 or 14, comprising:

a gate oxide film provided inside the trench and inside the outer peripheral portion trench; and

a peripheral portion gate electrode inside the outer peripheral portion trench provided on the gate oxide film, wherein

the gate electrode is provided on the gate oxide film inside the trench,

the gate oxide film and the peripheral portion gate electrode are formed so as to extend from an inside of the outer peripheral portion trench onto an upper surface of the semiconductor substrate of the cell portion, and

of the gate oxide film, a portion provided on the upper surface of the semiconductor substrate of the cell portion is thicker than a portion provided inside the trench.

### Appendix 16

The semiconductor device according to any one of appendixes 1 to 15, wherein a corner portion of the semiconductor substrate forming an opening of the trench is formed with an obtuse angle or a curved surface.

### Appendix 17

The semiconductor device according to any one of appendixes 1 to 16, wherein the semiconductor substrate is made with a wide bandgap semiconductor.

### Appendix 18

The semiconductor device according to appendix 17, wherein the wide bandgap semiconductor is silicon carbide, gallium nitride-based material, or diamond.

### Appendix 19

A method for manufacturing a semiconductor device, the method comprising:

in a semiconductor substrate including a cell portion and an outer peripheral portion outside the cell portion, forming a trench on an upper surface of the cell portion,

forming a gate electrode inside the trench,

forming a first interlayer film on an upper surface of the semiconductor substrate from the cell portion to the outer peripheral portion,

etching the first interlayer film so that the first interlayer film remains inside the trench,

after the etching of the first interlayer film, forming a second interlayer film on the upper surface of the semiconductor substrate from the cell portion to the outer peripheral portion such that the second interlayer film is formed on the first interlayer film inside the trench,

etching the second interlayer film so that the second interlayer film remains inside the trench and in the outer peripheral portion, and

after the etching of the second interlayer film, forming a main electrode on the second interlayer film so as to be in contact with the second interlayer film, wherein

one of the first interlayer film and the second interlayer film includes impurities.

In the semiconductor device and the method for manufacturing the semiconductor device according to the present disclosure, the trench is filled with the interlayer film containing impurities and having high filling properties. Therefore, the inside of the trench can be filled with the interlayer insulating film.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2025-016248, filed on Feb. 3, 2025 including specification, claims, drawings and summary, on which the Convention priority of the present application is based, are incorporated herein by reference in its entirety.

1. A semiconductor device comprising:
a semiconductor substrate including a cell portion and an outer peripheral portion outside the cell portion;
a gate electrode provided inside a trench formed on an upper surface of the cell portion;
a cell portion interlayer film inside the trench provided on the gate electrode;
an outer peripheral portion interlayer film provided on an upper surface of a mesa portion adjacent to the trench in the outer peripheral portion; and
a main electrode provided on the cell portion interlayer film and the outer peripheral portion interlayer film, and in contact with the cell portion interlayer film and the outer peripheral portion interlayer film, wherein
the cell portion interlayer film includes a first cell portion interlayer film provided on the gate electrode, and a second cell portion interlayer film provided on the first cell portion interlayer film and in contact with the main electrode, and
one of the first cell portion interlayer film and the second cell portion interlayer film includes impurities.

2. The semiconductor device according to claim 1, wherein the first cell portion interlayer film includes impurities,
the second cell portion interlayer film has a lower impurity concentration than the first cell portion interlayer film, and
an uppermost surface of the outer peripheral portion interlayer film that is in contact with the main electrode is formed of an interlayer film having a lower impurity concentration than the first cell portion interlayer film.

3. The semiconductor device according to claim 2, wherein the second cell portion interlayer film and the interlayer film forming the uppermost surface of the outer peripheral portion interlayer film do not include impurities.

4. The semiconductor device according to claim 1, wherein the outer peripheral portion interlayer film is a single layer.

5. The semiconductor device according to claim 1, wherein the second cell portion interlayer film is thinner than the outer peripheral portion interlayer film.

6. The semiconductor device according to claim 1, wherein an end portion adjacent to the trench, of the outer peripheral portion interlayer film is tapered.

7. A semiconductor device comprising:
a semiconductor substrate including a cell portion and an outer peripheral portion outside the cell portion;
a gate electrode provided inside a trench formed on an upper surface of the cell portion;
a cell portion interlayer film inside the trench provided on the gate electrode;
an outer peripheral portion interlayer film provided on an upper surface of a mesa portion adjacent to the trench in the outer peripheral portion; and
a main electrode provided on the cell portion interlayer film and the outer peripheral portion interlayer film and in contact with the cell portion interlayer film and the outer peripheral portion interlayer film, wherein
the cell portion interlayer film includes impurities,
the outer peripheral portion interlayer film includes a first outer peripheral portion interlayer film, and a second outer peripheral portion interlayer film provided on the first outer peripheral portion interlayer film and in contact with the main electrode, and
a portion of an upper surface of the outer peripheral portion interlayer film directly above the mesa portion and an end face of the outer peripheral portion interlayer film above the mesa portion are formed of a same type of interlayer film.

8. The semiconductor device according to claim 7, wherein the first outer peripheral portion interlayer film includes impurities,
the second outer peripheral portion interlayer film has a lower impurity concentration than the first outer peripheral portion interlayer film,
the interlayer film of the same type is the second outer peripheral portion interlayer film, and
an uppermost surface of the cell portion interlayer film that is in contact with the main electrode is formed of an interlayer film having a lower impurity concentration than the first outer peripheral portion interlayer film.

9. The semiconductor device according to claim 8, wherein the second outer peripheral portion interlayer film and the interlayer film forming the uppermost surface of the cell portion interlayer film do not include impurities.

10. The semiconductor device according to claim 7, wherein the cell portion interlayer film includes a first cell portion interlayer film provided on the gate electrode and a second cell portion interlayer film provided on the first cell portion interlayer film and in contact with the main electrode, and
the first cell portion interlayer film is thinner than the first outer peripheral portion interlayer film.

11. The semiconductor device according to claim 7, wherein an end portion adjacent to the trench, of the first outer peripheral portion interlayer film is tapered.

12. The semiconductor device according to claim 1, wherein the outer peripheral portion interlayer film is provided so as to expose a part of the mesa portion, and
the main electrode is in contact with the semiconductor substrate in the part of the mesa portion exposed from the outer peripheral portion interlayer film.

13. The semiconductor device according to claim 1, wherein an outer peripheral portion trench is formed on an upper surface of the outer peripheral portion of the semiconductor substrate.

14. The semiconductor device according to claim 13, wherein the outer peripheral portion interlayer film is formed so as to extend from an inside of the outer peripheral portion trench onto the mesa portion.

15. The semiconductor device according to claim 13, comprising:
a gate oxide film provided inside the trench and inside the outer peripheral portion trench; and
a peripheral portion gate electrode inside the outer peripheral portion trench provided on the gate oxide film, wherein
the gate electrode is provided on the gate oxide film inside the trench,
the gate oxide film and the peripheral portion gate electrode are formed so as to extend from an inside of the outer peripheral portion trench onto an upper surface of the semiconductor substrate of the cell portion, and
of the gate oxide film, a portion provided on the upper surface of the semiconductor substrate of the cell portion is thicker than a portion provided inside the trench.

16. The semiconductor device according to claim 1, wherein a corner portion of the semiconductor substrate forming an opening of the trench is formed with an obtuse angle or a curved surface.

17. The semiconductor device according to claim 1, wherein the semiconductor substrate is made with a wide bandgap semiconductor.

18. The semiconductor device according to claim 17, wherein the wide bandgap semiconductor is silicon carbide, gallium nitride-based material, or diamond.

19. A method for manufacturing a semiconductor device, the method comprising:
in a semiconductor substrate including a cell portion and an outer peripheral portion outside the cell portion, forming a trench on an upper surface of the cell portion,
forming a gate electrode inside the trench,
forming a first interlayer film on an upper surface of the semiconductor substrate from the cell portion to the outer peripheral portion,
etching the first interlayer film so that the first interlayer film remains inside the trench,
after the etching of the first interlayer film, forming a second interlayer film on the upper surface of the semiconductor substrate from the cell portion to the outer peripheral portion such that the second interlayer film is formed on the first interlayer film inside the trench,
etching the second interlayer film so that the second interlayer film remains inside the trench and in the outer peripheral portion, and
after the etching of the second interlayer film, forming a main electrode on the second interlayer film so as to be in contact with the second interlayer film, wherein
one of the first interlayer film and the second interlayer film includes impurities.

20. The semiconductor device according to claim 7, wherein the outer peripheral portion interlayer film is provided so as to expose a part of the mesa portion, and
the main electrode is in contact with the semiconductor substrate in the part of the mesa portion exposed from the outer peripheral portion interlayer film.

21. The semiconductor device according to claim 7, wherein an outer peripheral portion trench is formed on an upper surface of the outer peripheral portion of the semiconductor substrate.

22. The semiconductor device according to claim 21, wherein the outer peripheral portion interlayer film is formed so as to extend from an inside of the outer peripheral portion trench onto the mesa portion.

23. The semiconductor device according to claim 21, comprising:
a gate oxide film provided inside the trench and inside the outer peripheral portion trench; and
a peripheral portion gate electrode inside the outer peripheral portion trench provided on the gate oxide film, wherein
the gate electrode is provided on the gate oxide film inside the trench,
the gate oxide film and the peripheral portion gate electrode are formed so as to extend from an inside of the outer peripheral portion trench onto an upper surface of the semiconductor substrate of the cell portion, and
of the gate oxide film, a portion provided on the upper surface of the semiconductor substrate of the cell portion is thicker than a portion provided inside the trench.

24. The semiconductor device according to claim 7, wherein a corner portion of the semiconductor substrate forming an opening of the trench is formed with an obtuse angle or a curved surface.

25. The semiconductor device according to claim 7, wherein the semiconductor substrate is made with a wide bandgap semiconductor.

26. The semiconductor device according to claim 25, wherein the wide bandgap semiconductor is silicon carbide, gallium nitride-based material, or diamond.
